(19) United States
(12) Patent Application Publication
(10) Pub. No.: US 2026/0320266 A1
(43) Pub. Date: Oct. 15, 2026

(54) SYSTEMS AND METHODS FOR OPTIMIZING OIL AND GAS DEVELOPMENT PLANS

(71) Applicant: ConocoPhillips Company, Houston, TX (US)

(72) Inventors: Hui ZHOU, Houston, TX (US); Mazaruny Rincones, Houston, TX (US)

(21) Appl. No.: 19/642,753

(22) Filed: Apr. 9, 2026

Related U.S. Application Data
(60) Provisional application No. 63/787,254, filed on Apr. 11, 2025.

(51) Int. Cl. G06F 30/28; G06F 30/27

(52) U.S. Cl. CPC G06F 30/28; G06F 30/27

(57) ABSTRACT

Implementations claimed and described herein provide systems and methods for simulating natural resource reservoir data. The systems and methods use physics-embedded transformer to generate estimate data associated with well data.

### CROSS-REFERENCE TO RELATED APPLICATIONS

The present application claims priority to U.S. Provisional Patent Application No. 63/787,254 filed on Apr. 11, 2025, which is incorporated by reference in its entirety herein.

### FIELD

Aspects of the presently disclosed technology relate generally to optimizing natural resource production and more specifically to optimizing development plans of oil and gas production systems.

### BACKGROUND

Natural resource production systems require complex decisions during reservoir planning. Reservoir simulations are used to predict outcomes in response to changes in reservoir operation and planning. However, conventional reservoir simulation systems either use a pure data-drive approach that is not able to accurately quantify future well interactions or a pure model-drive approach that requires huge computational resources and is time consuming for complex and heterogeneous reservoirs, such as multi-stage fracturing of long horizontal wells in unconventional shales. These systems are inaccurate, inefficient, expensive, and cause delays in project planning and management decisions. It is with these observations in mind, among others, that various aspects of the present disclosure were conceived and developed.

### SUMMARY

Implementations described and claimed herein address the foregoing problems by providing systems and methods for predicting natural resource production data using a transformer that is embedded with pre-trained data. The pre-trained data is trained in accordance with first-principal physics using physics-based simulation models and analytical solutions. The implementations described and claimed herein allow for real time or near-real time prediction of predicting natural resource static data and dynamic data using the transformer. The implementations described and claimed herein require less data and are faster than conventional simulation systems, while also providing more accurate predictions than these systems.

In some implementations, a system for simulating natural resource production comprising a processing system in communication with a computing device and one or more databases over a network, the processing system receiving well data from at least one of the computing device or the one or more databases, and a physics-embedded transformer processing the well data to generate prediction data associated with a natural resource reservoir.

In some implementations, a method for simulating natural resource reservoir data, the method comprising receiving well data associated with a natural resource reservoir from at least one of a computing device or one or more databases, processing the well data using a physics-embedded transformer to generate processed well data, and generating, via the physics-embedded transformer, prediction data associated with the natural resource reservoir using the processed well data.

In some implementations, a non-transitory computer readable media storing computer-executable instructions that, when executed by at least one processor, cause a computing device to: receive well data associated with a natural resource reservoir, process the well data using a physics-embedded transformer to generate processed well data, and generate, via the physics-embedded transformer, prediction data associated with the natural resource reservoir using the processed well data.

Other implementations are also described and recited herein. Further, while multiple implementations are disclosed, still other implementations of the presently disclosed technology will become apparent to those skilled in the art from the following detailed description, which shows and describes illustrative implementations of the presently disclosed technology. As will be realized, the presently disclosed technology is capable of modifications in various aspects, all without departing from the spirit and scope of the presently disclosed technology. Accordingly, the drawings and detailed description are to be regarded as illustrative in nature and not limiting.

### BRIEF DESCRIPTION OF THE DRAWINGS

FIG. 1 illustrates an example communication system.

FIG. 2 illustrates an example processing system.

FIG. 3 illustrates an example transformer.

FIG. 4 illustrates an example computing system that may implement various aspects of the communication system.

FIG. 5 illustrates example operations for simulating natural resource reservoir data.

FIG. 6 illustrates example operations for training a transformer.

FIG. 7 illustrates an example user interface.

FIG. 8 illustrates an example plot graph generated by the processing system of FIG. 2.

FIG. 9 illustrates an example fracture fingerprint of a reservoir.

### DETAILED DESCRIPTION

Aspects of the present disclosure involve systems and methods to process historical data to predict properties of a reservoir. The systems and methods described herein use a transformer to provide a robust prediction of production responses and dynamic properties of a reservoir for later analysis of supply, operation, planning, function, finance, etc. The transformer leverages physics data relating to key performance indicators to provide a prediction for production output of a reservoir. This results in a more efficient platform that provides accurate predictions of reservoir properties for the oil and gas industry. Additional advantages of the presently disclosed technology will become apparent from the detailed description below.

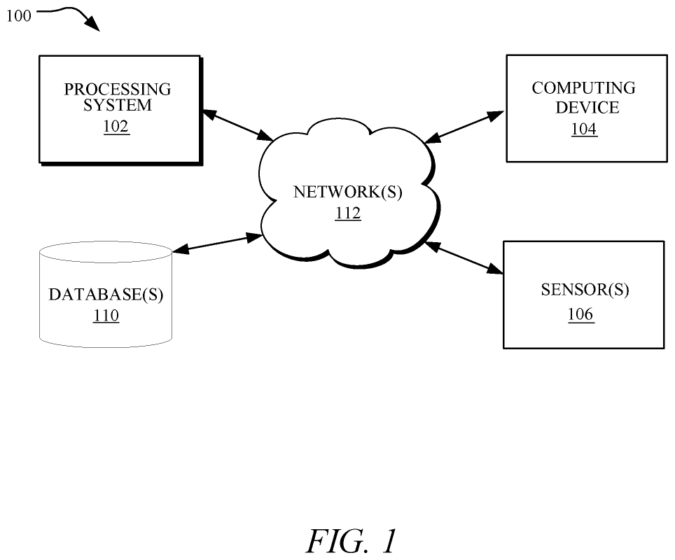

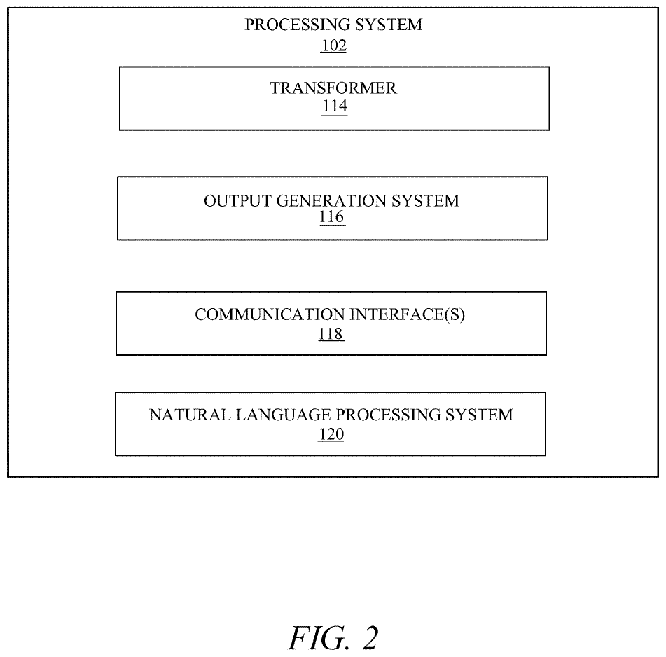

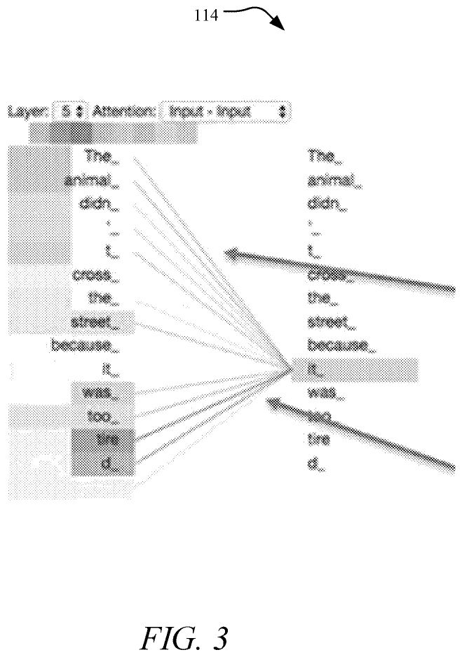

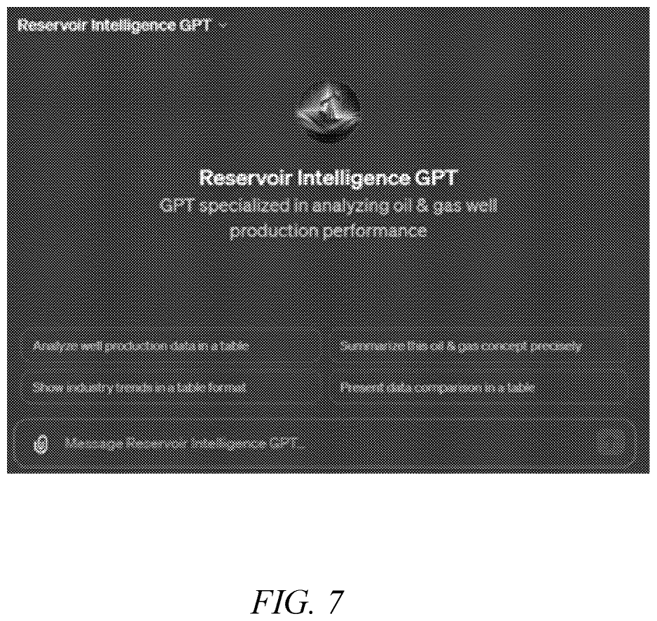

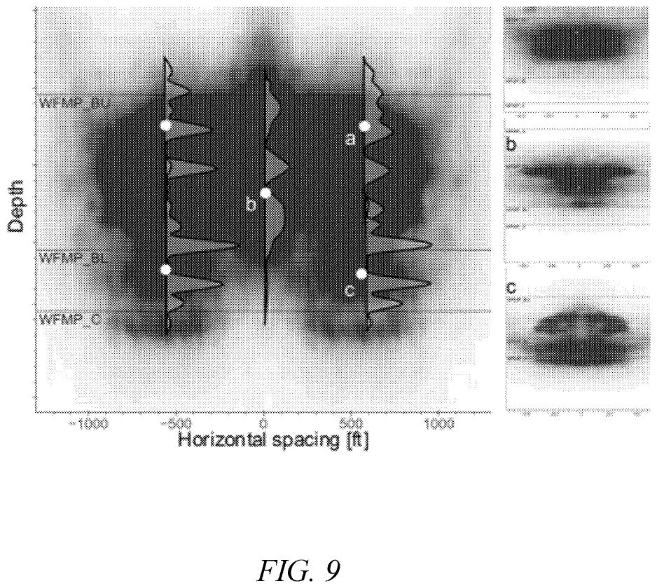

To begin a detailed description of an example system 100 for optimizing natural resource development. In an implementation, the system 100 processes well data, such as, for example, neighboring well data, parent well data, sibling well data, well-spacing data, well interaction data, geology data, etc., using a transformer that is embedded in general physics, such as first-principal physics, reference is made to FIGS. 1-9. The system 100 can include a processing system 102 configured to receive inputs by an operator via one or more input systems using, for example, a computing device 104 to input text, audio, and/or interact with an interactive user interface displayed on one or more output systems of, for example, the computing device 104, such as the user interface illustrated in FIG. 7. In an implementation, well data is received from the computing device 104, one or more sensors 106, and/or the one or more databases 110. In an implementation, at least a portion of the well data is obtained by one or more sensors 106 disposed in a well or at a surface during well tests or reservoir tests and/or well operation. The processing system 102, the computing device 104, and the one or more databases 110 are configured to interact with one another via a network(s) 112. As illustrated in greater detail below, any and/or all of the processing system 102, the computing device 104, and the one or more databases 110 may, in some instances, be special-purpose computing devices configured to perform specific functions.

The processing system 102 includes one or more computing devices (e.g., servers, routers, user interface devices, internet telephony computing device, and the like) that store and/or retrieve data in the one or more databases 110, generate user interfaces, execute a transformer 114, an output generation system 116, a natural language processing system 120 etc. by processing instructions. The processing system 102 may include a communication interface(s) 118 that is able to communicate with the one or more input systems and one or more output systems of, for example, the computing device 104, via the network(s) 112. For instance, the communication interface(s) 118 may be a network interface configured to support communication between the processing system 102 and/or the computing device 104 with the network(s) 112. The one or more input systems and one or more output systems may be part of the computing device 104 or separate from the computing device 104. The processing system 102 can be configured to train and maintain the transformer 114 to execute the techniques, as discussed in greater detail below. The processing system 102 can be configured to monitor and store (e.g., with appropriate permissions) data from the one or more databases 110 for further analysis and/or training of the transformer 114. In an implementation, the processing system 102 is configured to transmit output data to another computing device or database, such as the computing device 104 and/or the one or more databases 110. The processing system 102, the computing device 104, the one or more sensors 106, and the one or more databases 110 are configured to interact with one another via the network(s) 112. In an implementation, the well data is received directly from the one or more sensors 106 via a wired or wireless connection. In an implementation, the processing system 102 is associated with an organization or entity.

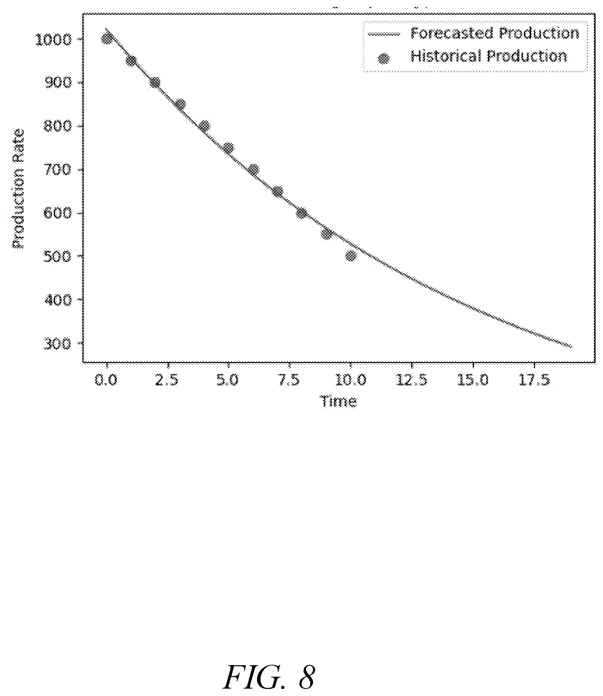

In an implementation, the computing device 104 includes one or more input systems and one or more output systems. For instance, the operator is able to input data to the processing system 102 via one or more interactive user interfaces using the computing device 104, such as the user interface illustrated in FIG. 7. In an implementation, the input data cis natural language input by the user into a search bar. The computing device 104 can be a smartphone, a tablet, a desktop computer, a laptop computer, or other personal computing device that may be used by an individual (e.g., the operator) to receive notification(s) and enter input data. In some instances, the computing device 104 may be used to display notifications and/or other alerts using graphical user interfaces, such as, for example, the plot graph illustrated in FIG. 8.

In an implementation, the processing system 102 includes instructions that direct and/or cause the natural language processing system 120 to execute processing techniques on the input data received by the one or more interactive user interfaces, such as, the user interface illustrated in FIG. 7, to generate processed input data. Based on the processed input data, the processing system 102 generates an output, such as, for example, the plot graph illustrated in FIG. 8, and performs one or more of the operations described herein. In an implementation, the natural language processing system 120 processes the input data using a large language model (LLM).

In an implementation, the processing system 102 includes instructions that direct and/or cause the transformer 114 to execute processing techniques on well data received from the computing device 104 and/or the one or more databases 110 to generate prediction data associated with the reservoir, such as for example static data and dynamic data. In an implementation, the static data includes one or more of geology and development data of the reservoir, and the dynamic data includes production data of the reservoir. In an implementation, the transformer 114 includes an encoder and a decoder. In an implementation, the transformer is a time series transformer.

In an implementation, the transformer 114 is trained using embedding data. In an implementation, the embedding data includes synthetic data derived from physics-based simulations and analytical solutions, such as, for example, first-principal physics, thereby resulting in a physics-embedded transformer that employs transformer architecture to embed pretrained data based on first-principal physics. In an implementation, the transformer 114 is an encoder-decoder neural network architecture with an attention mechanism. The transformer 114 is capable of processing long sequences. The transformer 114 is able to be re-trained to increase accuracy using transfer learning, thereby enabling fine-tuning of the transformer 114. For instance, the transformer 114 is re-trained using actual field data, such as, for example, geology data, development data, production data, etc.

In an implementation, the output generation system 116 is configured to perform one or more of the functions described herein. For example, the output generation system 116 may have instructions that direct and/or cause the output generation system 116 to generate a notification regarding the prediction data. For instance, the notification is audio, visual, and/or textual notification. In an implementation, the notification indicates that data has been estimated. In an implementation, the notification may be sent upon request and/or periodically to the computing device 104, such as, for example, e-mail, to indicate the estimated data. For instance, the notification may be sent, hourly, daily, weekly, monthly, etc. In another implementation, the notification indicates that the prediction data requires validation. In this implementation, the transformer 114 is updated based on user input with regards to the validation. In an implementation, the notification is presented via one or more interactive user interfaces, such as a plot or bar graph, generated by the output generation system 116 and transmitted, via the communication interface(s) 118, to the computing device 104 for display by the output system of the computing device 104. FIG. 8 illustrates an example plot graph generated by the output generation system 116. In another implementation, the output generation system 116 indicates a recommendation regarding reservoir management, operation, and/or planning based on the prediction data. In another implementation, the output generation system 116 generates instructions to automatically control reservoir management, operation, and/or planning based on the prediction data.

The processing system 102 may have instructions that direct and/or cause the processing system 102 to receive well and input data via the communication interface(s) 118, process the input data using the natural language processing system 120 to generate processed input data, process the well data in accordance with the processed input data using the transformer 114 to generate processed well data, generate prediction data using the processed well data, store the prediction data in the one or more databases 110, and generate output data using the output generation system 116.

The processing system 102 may have further instructions that direct and/or cause the processing system 102 to generate embedding data, train the transformer 114 using the embedding data, verify the transformer 114, re-train the transformer 114 based on the verification, and implement the transformer 114 to production.

The network(s) 112 can be any combination of one or more of a cellular network such as a 3rd Generation Partnership Project (3GPP) network, a third generation (3G) network, a fourth generation (4G) network, a fifth generation (5G) network, a Long-Term Evolution (LTE), an LTE Advanced Network, a Global System for Mobile Communications (GSM) network, a Universal Mobile Telecommunications System (UMTS) network, and the like. Moreover, the network(s) 112 can include any type of network, such as the Internet, an intranet, a Virtual Private Network (VPN), a Voice over Internet Protocol (VoIP) network, a wireless network (e.g., Bluetooth), a cellular network, a satellite network, combinations thereof, etc. The network(s) 112 can include communications network components such as, but not limited to gateways routers, servers, and registrars, which enable communication across the network(s) 112. In one implementation, the communications network components include multiple ingress/egress routers, which may have one or more ports, in communication with the network(s) 112.

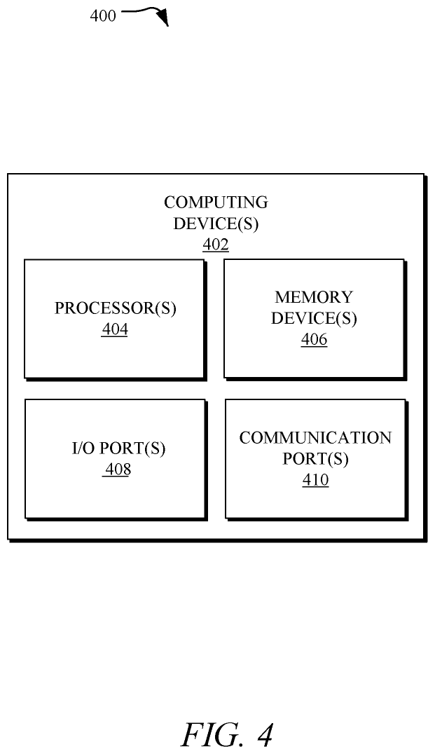

Turning to FIG. 4, a system 400 to process communication data can include one or more computing devices 402 for performing the techniques discussed herein. In one implementation, the one or more computing devices 402 include the computing device 104 and/or one or more servers of the processing system 102 to generate and execute the transformer 114, the output generation system 116, the natural language processing system 120, etc. as a software application and/or a module or algorithmic component of software.

In some instances, the computing device 402 can include a computer, a personal computer, a desktop computer, a laptop computer, a terminal, a workstation, a server device, a cellular or mobile phone, a mobile device, a smart mobile device a tablet, a wearable device (e.g., a smart watch, smart glasses, a smart epidermal device, etc.) a multimedia console, a television, an Internet-of-Things (IoT) device, a smart home device, a medical device, a virtual reality (VR) or augmented reality (AR) device, a vehicle (e.g., a smart bicycle, an automobile computer, etc.), and/or the like. The computing device 402 may be integrated with, form a part of, or otherwise be associated with the systems 100-400. It will be appreciated that specific implementations of these devices may be of differing possible specific computing architectures not all of which are specifically discussed herein but will be understood by those of ordinary skill in the art.

The computing device 402 may be a computing system capable of executing a computer program product to execute a computer process. Data and program files may be input to the computing device 402, which reads the files and executes the programs therein. Some of the elements of the computing device 402 include one or more processors 404, one or more memory devices 406, and/or one or more ports, such as input/output (IO) port(s) 408 and communication port(s) 410. Additionally, other elements that will be recognized by those skilled in the art may be included in the computing device 402 but are not explicitly depicted in FIG. 4 or discussed further herein. Various elements of the computing device 402 may communicate with one another by way of the communication port(s) 410 and/or one or more communication buses, point-to-point communication paths, or other communication means.

The processor 404 may include, for example, a central processing unit (CPU), a microprocessor, a microcontroller, a digital signal processor (DSP), and/or one or more internal levels of cache. There may be one or more processors 404, such that the processor 404 comprises a single central-processing unit, or a plurality of processing units capable of executing instructions and performing operations in parallel with each other, commonly referred to as a parallel processing environment.

The computing device 402 may be a conventional computer, a distributed computer, or any other type of computer, such as one or more external computers made available via a cloud computing architecture. The presently described technology is optionally implemented in software stored on the data storage device(s) such as the memory device(s) 406, and/or communicated via one or more of the I/O port(s) 408 and the communication port(s) 410, thereby transforming the computing device 402 in FIG. 4 to a special purpose machine for implementing the operations described herein. Moreover, the computing device 402, as implemented in the systems 100-400, receives various types of input data (e.g., the input data, well data, etc.) and transforms the input data through various stages of the data flow into new types of data files (e.g., embedding data). Moreover, these new data files are transformed further into the prediction data and sent to the computing device 104 to provide information regarding the predictions, which enables the computing device 402 to do something it could not do before—simulating reservoir production data using a physics-embedded transformer.

Additionally, the systems and operations disclosed herein represent an improvement to the technical field of machine learning processing. For instance, the processing system 102 can generate estimate data with less data and fewer computing resources without human intervention. Moreover, data can be leveraged from different data sources with varying levels of abstraction to provide a highly efficient and effective estimation of reservoir data. These techniques are rooted in technology and could not have existed prior to the advent of machine learning analytics and simulation software.

The one or more memory device(s) 406 may include any non-volatile data storage device capable of storing data generated or employed within the computing device 402, such as computer executable instructions for performing a computer process, which may include instructions of both application programs and an operating system (OS) that manages the various components of the computing device 402. The memory device(s) 406 may include, without limitation, magnetic disk drives, optical disk drives, solid state drives (SSDs), flash drives, and the like. The memory device(s) 406 may include removable data storage media, non-removable data storage media, and/or external storage devices made available via a wired or wireless network architecture with such computer program products, including one or more database management products, web server products, application server products, and/or other additional software components. Examples of removable data storage media include Compact Disc Read-Only Memory (CD-ROM), Digital Versatile Disc Read-Only Memory (DVD-ROM), magneto-optical disks, flash drives, and the like. Examples of non-removable data storage media include internal magnetic hard disks, SSDs, and the like. The one or more memory device(s) 406 may include volatile memory (e.g., dynamic random access memory (DRAM), static random access memory (SRAM), etc.) and/or non-volatile memory (e.g., read-only memory (ROM), flash memory, etc.).

Computer program products containing mechanisms to effectuate the systems and methods in accordance with the presently described technology may reside in the memory device(s) 406 which may be referred to as machine-readable media. It will be appreciated that machine-readable media may include any tangible non-transitory medium that is capable of storing or encoding instructions to perform any one or more of the operations of the present disclosure for execution by a machine or that is capable of storing or encoding data structures and/or modules utilized by or associated with such instructions. Machine-readable media may include a single medium or multiple media (e.g., a centralized or distributed database, and/or associated caches and servers) that store the one or more executable instructions or data structures.

In some implementations, the computing device 402 includes one or more ports, such as the I/O port(s) 408 and the communication port(s) 410, for communicating with other computing, network, or vehicle computing devices. It will be appreciated that the I/O port 408 and the communication port 410 may be combined or separate and that more or fewer ports may be included in the computing device 402.

The I/O port 408 may be connected to an I/O device, or other device, by which information is input to or output from the computing device 402. Such I/O devices may include, without limitation, one or more input devices, output devices, and/or environment transducer devices.

In one implementation, the input devices convert a human-generated signal, such as, human voice, physical movement, physical touch or pressure, and/or the like, into electrical signals as input data into the computing device 402 via the I/O port 408. Similarly, the output devices may convert electrical signals received from the computing device 402 via the I/O port 408 into signals that may be sensed as output by a human, such as sound, light, and/or touch. The input device may be an alphanumeric input device, including alphanumeric and other keys for communicating information and/or command selections to the processor 404 via the I/O port 408. The input device may be another type of user input device including, but not limited to direction and selection control devices, such as a mouse, a trackball, cursor direction keys, a joystick, and/or a wheel; one or more sensors, such as a camera, a microphone, a positional sensor, an orientation sensor, an inertial sensor, and/or an accelerometer; and/or a touch-sensitive display screen (“touchscreen”). The output devices may include, without limitation, a display, a touchscreen, a speaker, a tactile and/or haptic output device, and/or the like. In some implementations, the input device and the output device may be the same device, for example, in the case of a touchscreen.

The environment transducer devices convert one form of energy or signal into another for input into or output from the computing device 402 via the I/O port 408. For example, an electrical signal generated within the computing device 402 may be converted to another type of signal, and/or vice-versa. In one implementation, the environment transducer devices sense characteristics or aspects of an environment local to or remote from the computing device 402, such as, light, sound, temperature, pressure, magnetic field, electric field, chemical properties, physical movement, orientation, acceleration, gravity, and/or the like.

In one implementation, the communication port 410 is connected to the network(s) 112 so the computing device 402 can receive network data useful in executing the methods and systems set out herein as well as transmitting information and network configuration changes determined thereby. Stated differently, the communication port 410 connects the computing device 402 to one or more communication interface devices configured to transmit and/or receive information between the computing device 402 and other devices by way of one or more wired or wireless communication networks or connections. Examples of such networks or connections include, without limitation, Universal Serial Bus (USB), Ethernet, Wi-Fi, Bluetooth®, Near Field Communication (NFC), and so on. One or more such communication interface devices may be utilized via the communication port 410 to communicate with one or more other machines, either directly over a point-to-point communication path, over a wide area network (WAN) (e.g., the Internet), over a local area network (LAN), over a cellular network (e.g., third generation (3G), fourth generation (4G), Long-Term Evolution (LTE), fifth generation (5G), etc.) or over another communication means. Further, the communication port 410 may communicate with an antenna or other link for electromagnetic signal transmission and/or reception.

In an example, the processing system 102, the transformer 114, the output generation system 116, the natural language processing system 120, etc., and/or other software, modules, services, and operations discussed herein may be embodied by instructions stored on the memory device(s) 406 and executed by the processor 404.

The system set forth in FIG. 4 is but one possible example of a computing device 402 or computer system that may be configured in accordance with aspects of the present disclosure. It will be appreciated that other non-transitory tangible computer-readable storage media storing computer-executable instructions for implementing the presently disclosed technology on a computing system may be utilized. In the present disclosure, the methods disclosed may be implemented as sets of instructions or software readable by the computing device 402.

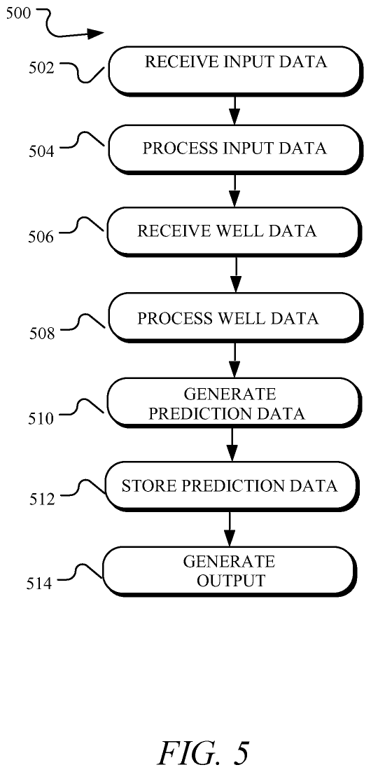

FIG. 5 depicts an example method 500 for simulating natural resource reservoir data, which can be performed by any of the systems 100-400 discussed herein. The method 500 can, in some instances, occur in real time.

At operation 502, the method 500 can receive input data via the communication interface(s) 118 from the computing device 104.

At operation 504, the method 500 can process the input data using the natural language processing system 120 to generate processed input data.

At operation 506, the method 500 can receive well data via the communication interface(s) 118 from the database(s) 110. In an implementation, the well data is inputted by a user via one or more input systems of the computing device 104. In an implementation, the well data is obtained using the one or more sensors 106.

At operation 508, the method 500 can process the well data using the transformer 114 to generate processed well data.

At operation 510, the method 500 can generate, via the transformer 114, prediction data using the processed well data in accordance with the processed input data.

At operation 512, the method 500 can store the prediction data in the one or more databases 110.

At operation 514, the method 500 can generate an output using the output generation system 116.

It is to be understood that the specific order or hierarchy of operations in the method depicted in FIG. 5 and throughout this disclosure are instances of example approaches and can be rearranged while remaining within the disclosed subject matter. For instance, any of the operations depicted in FIG. 5 may be omitted, repeated, performed in parallel, performed in a different order, and/or combined with any other of the operations depicted in FIG. 5 or discussed herein.

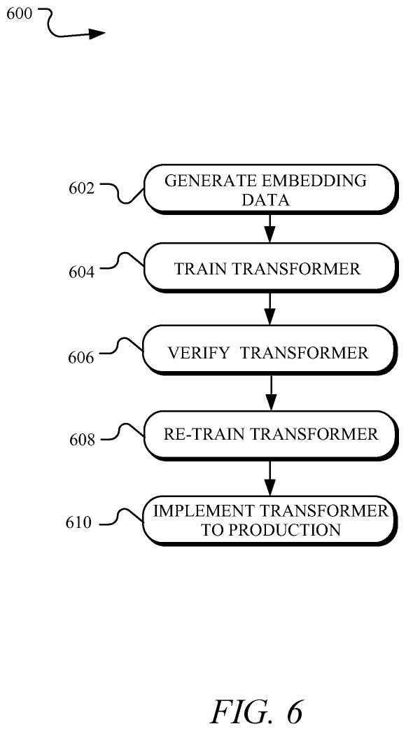

FIG. 6 depicts an example method 600 for training a transformer, which can be performed by any of the systems 100-400 discussed herein. The method 500 can, in some instances, occur in real time.

At operation 602, the method 600 can generate embedding data based on first-principal physics.

At operation 604, the method 600 can train the transformer 114 using the embedding data.

At operation 606, the method 600 can verify the transformer 114. In an implementation, the transformer is verified based on a comparison of prediction data generated by the transformer 114 with known data. The transformer is verified when the prediction data is within an error threshold of the known data.

At operation 608, the method 500 can re-train the transformer using transfer learning. In an implementation, the actual field data, such as, for example, geology data, development data, production data, etc. is used to retrain the transformer.

At operation 610, the method 600 can implement the transformer to production.

In an implementation, the method 600 is repeated until an acceptable error threshold is reached. It is to be understood that the specific order or hierarchy of operations in the method depicted in FIG. 6 and throughout this disclosure are instances of example approaches and can be rearranged while remaining within the disclosed subject matter. For instance, any of the operations depicted in FIG. 6 may be omitted, repeated, performed in parallel, performed in a different order, and/or combined with any other of the operations depicted in FIG. 6 or discussed herein.

Some exemplary applications of the attached disclosure include one or more of the following: consortium processing, personalized completion design, learning from pilot projects for future completion optimization, Artificial-intelligence (AI) assistant, data from market, competitors assistance high-level decision making, AI outlooks, engineering forecasts, capital spending planning, early time unconventional forecast, AI-assisted operated by others data collection, bottom hole pressure estimator for mature wells, reservoir transformer for reservoir simulation, AI-Imaging processing to edit reservoir models, generate geological models from conversational descriptions and user interactions, generate reservoir simulation models from conversational descriptions and user interactions, modify user experience such as user edits from conversation, time series transformer for production forecast, fully automated type well identification, well description (logs, gun barrel, etc.), dynamic time warping for completion, drilling, production performance characterization for real-time maintenance and optimization, refracturing candidate selection, automated decline curve identification using image pattern recognition, underground viewing, augment emission detection from google earth image with field instruments, and heave tracking with Light Detection and Ranging (LiDAR).

Furthermore, any term of degree such as, but not limited to, “substantially,” as used in the description and the appended claims, should be understood to include an exact, or a similar, but not exact configuration. Similarly, the terms “about” or “approximately,” as used in the description and the appended claims, should be understood to include the recited values or a value that is three times greater or one third of the recited values. For example, about 3 mm includes all values from 1 mm to 9 mm, and approximately 50 degrees includes all values from 16.6 degrees to 150 degrees.

Lastly, the terms “or” and “and/or,” as used herein, are to be interpreted as inclusive or meaning any one or any combination. Therefore, “A, B, or C” or “A, B, and/or C” mean any of the following: “A,” “B,” or “C”; “A and B”; “A and C”; “B and C”; “A, B and C.” An exception to this definition will occur only when a combination of elements, functions, steps or acts are in some way inherently mutually exclusive.

While the present disclosure has been described with reference to various implementations, it will be understood that these implementations are illustrative and that the scope of the present disclosure is not limited to them. Many variations, modifications, additions, and improvements are possible. More generally, implementations in accordance with the present disclosure have been described in the context of particular implementations. Functionality may be separated or combined differently in various implementations of the disclosure or described with different terminology. These and other variations, modifications, additions, and improvements may fall within the scope of the disclosure as defined in the claims that follow.

What is claimed is:

1. A system for simulating natural resource production, the system comprising:
a processing system in communication with a computing device and one or more databases over a network, the processing system receiving well data from at least one of the computing device or the one or more databases; and
a physics-embedded transformer processing the well data to generate prediction data associated with a natural resource reservoir.

2. The system of claim 1, further comprising:
an output generation system configured to generate a notification associated with the prediction data, the processing system configured to transmit the notification to the computing device to cause the notification to be presented using one or more output systems of the computing device.

3. The system of claim 1, further comprising:
a natural language processing system receiving input data obtained using one or more input systems of the computing device, the physics-embedded transformer processing the well data based on the input data.

4. The system of claim 1, wherein the processing system is configured to transmit the prediction data to the one or more databases over the network to cause the one or more databases to store the prediction data.

5. The system of claim 1, wherein the well data includes at least one of neighboring well data, parent well data, sibling well data, well-spacing data, well interaction data, or geology data.

6. The system of claim 1, wherein the physics-embedded transformer is an encoder-decoder neural network architecture with an attention mechanism.

7. The system of claim 1, wherein the prediction data at least one of static data or dynamic data associated with the natural resource reservoir.

8. The system of claim 7, wherein the static data includes at least one of geology data and development data of the natural resource reservoir, and the dynamic data includes production data of the natural resource reservoir.

9. The system of claim 1, wherein the physics-embedded transformer is embedded with pretrained data based on first-principal physics.

10. The system of claim 1, wherein the physics-embedded transformer is re-trained using actual field data.

11. A method for simulating natural resource reservoir data, the method comprising:
receiving well data associated with a natural resource reservoir from at least one of a computing device or one or more databases;
processing the well data using a physics-embedded transformer to generate processed well data; and
generating, via the physics-embedded transformer, prediction data associated with the natural resource reservoir using the processed well data.

12. The method of claim 11, further comprising:
generating a notification associated with the prediction data; and
transmitting the notification to the computing device to cause the notification to be presented using one or more output systems of the computing device.

13. The method of claim 11, wherein the physics-embedded transformer is embedded with pretrained data based on first-principal physics.

14. The method of claim 11, wherein the prediction data at least one of static data or dynamic data associated with the natural resource reservoir.

15. A non-transitory computer readable media storing computer-executable instructions that, when executed by at least one processor, cause a computing device to:
receive well data associated with a natural resource reservoir;
process the well data using a physics-embedded transformer to generate processed well data; and
generate, via the physics-embedded transformer, prediction data associated with the natural resource reservoir using the processed well data.

16. The non-transitory computer readable media of claim 15 storing further computer-executable instructions that, when executed by the at least one processor, further cause the computing device to:
generate a notification associated with the prediction data; and
transmit the notification to the computing device to cause the notification to be presented using one or more output systems of the computing device.

17. The non-transitory computer readable media of claim 15, wherein the physics-embedded transformer is embedded with pretrained data based on first-principal physics.

18. The non-transitory computer readable media of claim 15, wherein the prediction data at least one of static data or dynamic data associated with the natural resource reservoir.

19. The non-transitory computer readable media of claim 15, wherein the well data includes at least one of neighboring well data, parent well data, sibling well data, well-spacing data, well interaction data, or geology data.

20. The non-transitory computer readable media of claim 15, wherein the physics-embedded transformer is an encoder-decoder neural network architecture with an attention mechanism.
